(19) United States
(12) Patent Application Publication
(10) Pub. No.: US 2024/0332125 A1
(43) Pub. Date: Oct. 3, 2024

(54) 2D FILLERS FOR REDUCED CTE FOR PID

(71) Applicant: Intel Corporation, Santa Clara, CA (US)

(72) Inventors: Kyle ARRINGTON, Gilbert, AZ (US); Clay ARRINGTON, Queen Creek, AZ (US); Bohan SHAN, Chandler, AZ (US); Haobo CHEN, Gilbert, AZ (US); Srinivas V. PIETAMBARAM, Chandler, AZ (US); Gang DUAN, Chandler, AZ (US); Ziyin LIN, Chandler, AZ (US); Hongxia FENG, Chandler, AZ (US); Yiqun BAI, Chandler, AZ (US); Xiaoying GUO, Chandler, AZ (US); Dingying XU, Chandler, AZ (US); Bai NIE, Chandler, AZ (US)

(21) Appl. No.: 18/128,848

(22) Filed: Mar. 30, 2023

(51) Int. Cl. H01L 23/373; H01L 21/48; H01L 23/24; H01L 23/498

(52) U.S. Cl. CPC H01L 23/3737; H01L 21/4857; H01L 21/486; H01L 23/24; H01L 23/49822; H01L 23/49827

(57) ABSTRACT

Embodiments disclosed herein include a package substrate. In an embodiment, the package substrate comprises a first layer and a second layer over the first layer. In an embodiment, the second layer comprises a dielectric material including sulfur. In an embodiment, fillers are within the second layer. In an embodiment, the fillers have a volume fraction that is less than approximately 0.2.

### TECHNICAL FIELD

Embodiments of the present disclosure relate to electronic systems, and more particularly to package substrates that include photoimageable dielectrics (PIDs) that have a reduced coefficient of thermal expansion (CTE) as the result of two dimensional (2D) fillers.

### BACKGROUND

Photoimageable dielectrics (PIDs) are a class of materials that are of growing popularity in the semiconductor industry. PIDs are particularly useful in semiconductor packaging applications. For example, the PID can be used as a buildup layer in order to form conductive structures above and/or below the core. PID materials typically include a dielectric bulk material with a solubility switch, such as a photo-acid generator (PAG). The solubility switch, when activated by electromagnetic radiation, enables a cross-linking reaction in the bulk material. After exposure, either the cross-linked region or the unaltered region is removed in a developing process. PIDs have been developed with low dielectric constants necessary for use in electronic packaging applications.

However, currently available PIDs suffer from high coefficients of thermal expansion (CTEs). This is particularly problematic when the PIDs are coupled to low CTE materials, such as a silicon die. The difference in the CTEs between the PID and the silicon produces a high level of stress in the electronic package, and can lead to reliability concerns. One approach for improving (i.e., reducing) the CTE of the PID is to provide a filler in the bulk material. Fillers such as silicon dioxide may be incorporated into the PID. Unfortunately, high filler volume fractions are needed in order to provide the desired CTE reductions. Further, at high volume fractions, the filler particles may even block or reflect the electromagnetic radiation, and the exposure and develop process is negatively impacted. In addition, high volume fractions for filler particles, raises modulus values. This lowers stress relaxation properties and negatively impacts reliability. Viscosities of such formulations are also increased, which negatively impacts dispense and coating capabilities.

### BRIEF DESCRIPTION OF THE DRAWINGS

FIG. 1A is a cross-sectional illustration of a first layer of a package substrate, in accordance with an embodiment.

FIG. 1B is a cross-sectional illustration of the first layer after a photoimageable dielectric (PID) is provided over the first layer, in accordance with an embodiment.

FIG. 1C is a cross-sectional illustration of the PID being exposed to electromagnetic radiation, in accordance with an embodiment.

FIG. 1D is a cross-sectional illustration of the PID after being developed, in accordance with an embodiment.

FIG. 1E is a cross-sectional illustration of the PID after a via is formed through the PID, in accordance with an embodiment.

FIG. 2 is a cross-sectional illustration of a PID with a high volume fraction of filler particles that negatively impacts exposure, in accordance with an embodiment.

FIG. 3 is a cross-sectional illustration of a PID with two dimensional (2D) filler particles at a low volume fraction, in accordance with an embodiment.

FIG. 4 is a zoomed in illustration of one of the 2D filler particles in a PID, in accordance with an embodiment.

FIG. 5 is a graph showing the decrease in coefficient of thermal expansion (CTE) relative to the volume fraction of the 2D filler particles in the PID, in accordance with an embodiment.

FIG. 6A is a cross-sectional illustration of a first layer of a package substrate, in accordance with an embodiment.

FIG. 6B is a cross-sectional illustration of the first layer after a PID with 2D filler particles is provided over the first layer, in accordance with an embodiment.

FIG. 6C is a cross-sectional illustration of the PID being exposed to electromagnetic radiation, in accordance with an embodiment.

FIG. 6D is a cross-sectional illustration of the PID after being developed, in accordance with an embodiment.

FIG. 6E is a cross-sectional illustration of the PID after a via is formed through the PID, in accordance with an embodiment.

FIG. 7 is a cross-sectional illustration of an electronic system that comprises PIDs with 2D filler particles, in accordance with an embodiment.

FIG. 8 is a schematic of a computing device built in accordance with an embodiment.

### EMBODIMENTS OF THE PRESENT DISCLOSURE

Described herein are electronic systems, and more particularly package substrates that include photoimageable dielectrics (PIDs) that have a reduced coefficient of thermal expansion (CTE) as the result of two dimensional (2D) fillers, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, existing photoimageable dielectrics (PIDs) are beneficial for semiconductor packaging applications, but they come with some drawbacks. One drawback is that the coefficient of thermal expansion (CTE) of such materials is significantly higher than the CTE of the die (e.g., silicon die) that will ultimately be attached to the package substrate. As such, thermal cycling may result in stress and damage in the system. Accordingly, embodiments disclosed herein include PID material systems that reduce the CTE of the material without significant impacts to the exposure based solubility switch. Further, embodiments allow for improved modulus properties compared to traditional silica fillers, which improves system reliability.

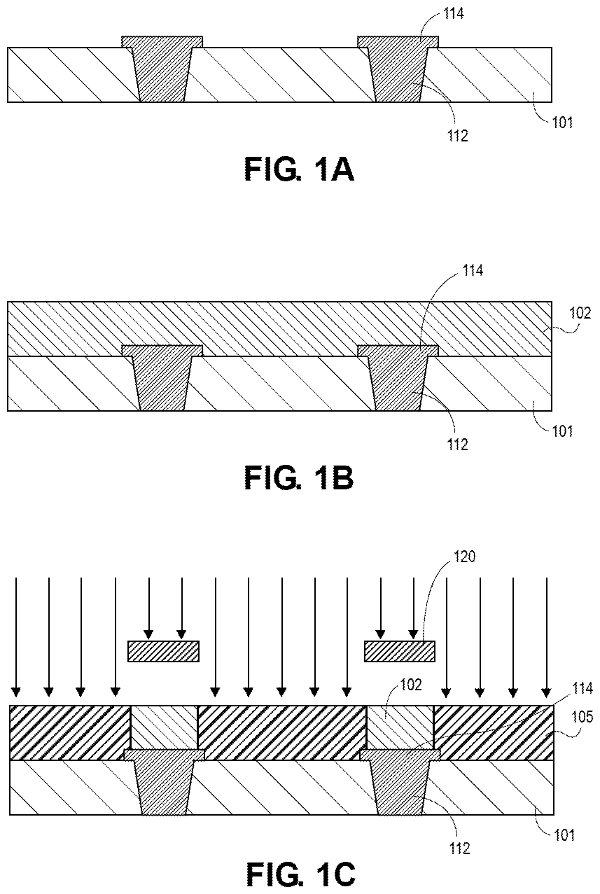

To provide context, FIGS. 1A-1E illustrate a process flow for how a PID may be used in electronic packaging applications. While the specific applications described herein include the use of the PID material in a package substrate, it is to be appreciated that similar PID materials may be used in other aspects of semiconductor fabrications, (e.g., wafer level processing and the like). In FIGS. 1A-1E, the PID material is a generic PID material that is not tuned for low CTE applications. Accordingly, such a solution may not be compatible with high performance applications where CTE mismatch needs to be minimized.

Referring now to FIG. 1A, a cross-sectional illustration of a first layer 101 in a package substrate is shown, in accordance with an embodiment. The first layer 101 may be a core layer. For example, the first layer 101 may be an organic core, a glass core, or the like. However, it is to be appreciated that the first layer 101 may be any of the layers in a package substrate. In some instances (e.g., when the first layer 101 is a core), the first layer 101 may not be a PID. However, in other instances the first layer 101 may be a PID.

The first layer 101 may include a via 112. The via 112 may have tapered sidewalls in some instances. Tapered sidewalls may be indicative of a laser drilling or a laser assisted etching process. However, in some embodiments, the via 112 may have substantially vertical sidewalls. Such embodiments may be exhibited when a lithography process is used to pattern the opening for the via 112. The via 112 may comprise an electrically conductive material, such as copper.

In an embodiment, a routing layer may be provided over the first layer 101. As shown in FIG. 1A, the routing layer may include pads 114 that are provided over the vias 112. The pads 114 may include an electrically conductive material, such as copper. In an embodiment, traces (not shown) may also be provided over the first layer 101. In subsequent processing operations, the pads 114 may be used as a seed layer in order to plate up overlying vias.

Referring now to FIG. 1B, a cross-sectional illustration of the first layer 101 after a PID 102 is provided over a top surface of the first layer 101, in accordance with an embodiment. In an embodiment, the PID 102 may be a dielectric material that includes a solubility switch mechanism. For example, a photo-acid generator (PAG) may be included in the PID 102. In some implementations, a PAG PID comprises a sulfur-containing compound and, hence, in such implementations, PID 102 comprises sulfur atoms. Upon exposure to a particular wavelength of electromagnetic radiation, the PAG generates an acid that initiates a cross-linking response in the PID 102. Depending on the tone of the PID 102, the cross-linked regions or the unaltered regions are removed during developing.

In an embodiment, the PID 102 may be provided over the first layer 101 with any suitable deposition process. In one instance, the PID 102 may be laminated over the first layer 101. In some embodiments, the PID 102 may be baked or otherwise treated after deposition. Other deposition processes may also be used. For example, if the PID 102 is a liquid material during dispense, the PID 102 may be applied with a spin coating process, and subsequently baked to remove some or all of the solvent.

Referring now to FIG. 1C, a cross-sectional illustration of the PID 102 during an exposure process is shown, in accordance with an embodiment. In an embodiment, the exposure process may include a mask 120 or the like. Openings in the mask 120 allow for electromagnetic radiation (indicated by the arrows) to pass through the mask 120 and interact with the underlying PID 102. As shown, the mask 120 may be oriented so that the pads 114 on the first layer 101 are covered by the mask 120.

As shown, the PID 102 is converted to include exposed regions 105 in the regions that interact with the electromagnetic radiation. The exposed regions 105 may be regions of higher cross-linking than the remainder of the PID 102. The increased cross-linking percentage may be attributable to the activation of PAGs or the like. In an embodiment, the electromagnetic radiation may be produced by a mercury or a mercury-xenon lamp and include electromagnetic radiation at a wavelength between approximately 360 nm and approximately 420 nm.

Referring now to FIG. 1D, a cross-sectional illustration of the PID 102 after a developing process is shown, in accordance with an embodiment. In an embodiment, the developing process may include a wet chemistry. The wet chemistry selectively etches the unexposed regions of the PID 102 in order to form openings 115 through the exposed regions 105. The openings 115 may be aligned over the pads 114. In some embodiments, a width of the opening 115 is narrower than a width of the pad 114. Further, in some embodiments, the sidewalls of the openings 115 are substantially vertical. As such, the subsequently formed via (not shown in FIG. 1D) may have sidewall orientations that are different than those of the via 112 in the first layer 101.

Referring now to FIG. 1E, a cross-sectional illustration of the cross-linked PID 105 after vias 110 are plated in the openings 115 is shown, in accordance with an embodiment. In an embodiment, the vias 110 may be plated with any suitable plating process. In one embodiment, the plating may be an electroless plating process, an electrolytic plating process, or the like. The pad 114 at the bottom of the opening 115 may function as a seed layer in order to plate up the via 110. In other embodiments, a seed layer (not shown) may be provided over the surfaces of the exposed PID 105 in order to enable plating in the opening 115 and over the top surface of the exposed PID 105. The residual material over the top surface of the exposed PID 105 may be polished back. Alternatively, a mask layer may be provided over the exposed PID 105 to selectively form copper over the exposed PID 105. For example, pads, traces, and the like may be formed over the exposed PID 105 during the plating process in some embodiments.

As noted above, the PID 102 in FIGS. 1A-1E is a standard PID material. That is, there are not significant amounts of filler particles. Since there are no (or minimal) filler particles, the lithography operation (e.g., exposure and developing) can proceed without much difficulty. However, such a PID material will have a relatively high CTE. The high CTE may result in a significant mismatch with an overlying die (e.g., a silicon die) that will ultimately be attached to the package substrate. Due to the high CTE mismatch, stresses will build up in the system during thermal cycling, and can result in significant reliability concerns.

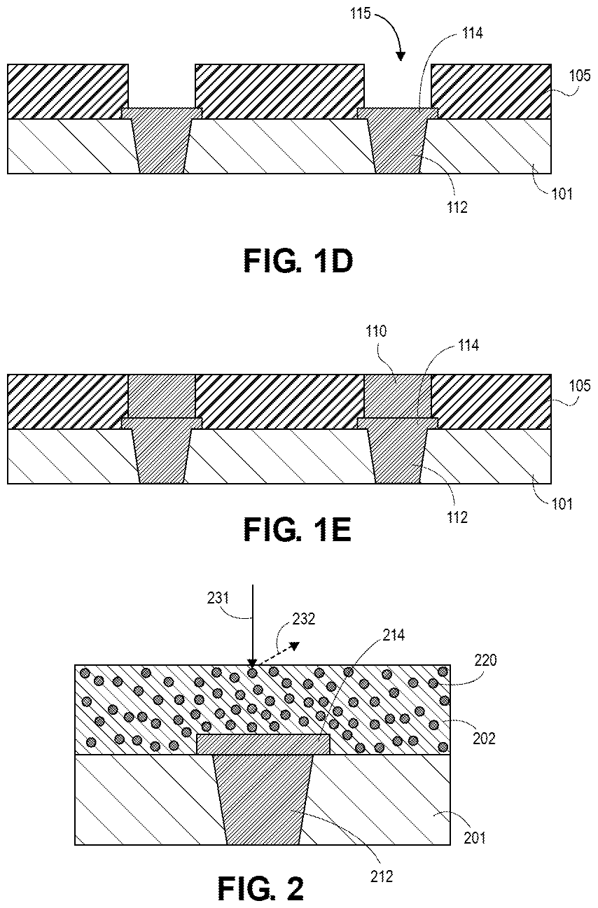

Accordingly, some approaches for improved CTE of the package substrate include inserting filler particles in the PID. An example of such a structure is shown in FIG. 2. The structure in FIG. 2 may comprise a first layer 201. The first layer 201 may be a core layer (e.g., organic core, glass core, etc.), or the first layer 201 may be a buildup layer. A via 212 may pass through the first layer 201 in some instances, and a pad 214 may be provided over the via 212.

In an embodiment, a PID 202 is provided over the first layer 201. The PID 202 may be applied with any suitable deposition process, such as those described in greater detail above (e.g., lamination, etc.). In contrast to the unfilled PID 102 in FIGS. 1A-1E, the PID 202 in FIG. 2 includes fillers 220. The fillers 220 may be particles that are mixed in with the bulk PID 202 material. The fillers 220 may be any filler suitable for decreasing the CTE of the PID 202. For example, the fillers 220 may comprise silicon and oxygen (e.g., SiO₂). The fillers 220 may have dimensions that are on the micron scale in some embodiments. In an embodiment, the volume fraction of the fillers may be approximately 0.5 or greater or approximately 0.8 or greater. That is, a significant portion of the PID 202 may comprise fillers 220.

While the fillers 220 provide improved CTE performance, the fillers 220 have a downside. Particularly, the fillers 220 make the solubility switch harder to achieve. For one instance, electromagnetic radiation 231 that is incident on the PID 202 may run into one of the filler 220 particles. The electromagnetic radiation 231 may be absorbed or reflected (e.g., reflected light 232) by the fillers 220. That is, instead of being absorbed by the solubility switching mechanism (e.g., a PAG), the radiation 231 is lost. Therefore, longer exposures may be needed to provide the necessary dose of electromagnetic radiation 231. Also, the fillers 220 may completely block some portions of the PID 202 and result in patterning defects. Further, high filler 220 loading results in high moduli, which negatively impacts stress relaxation.

Accordingly, embodiments disclosed herein include PID materials that are tuned for low CTE with minimal filler volume percentages. More particularly, the fillers that are chosen for the PID enable a significant reduction in the CTE with volume fractions that are approximately 0.2 or lower or approximately 0.1 or lower. In some embodiments, a volume fraction of 0.05 may result in a CTE reduction of approximately fifty percent. The particular filler particles that are used herein may be two-dimensional (2D) filler particles. The 2D nature of the filler particles enhances the CTE response without high loading percentages. As used herein, volume fraction is a measure where 1.0 equates to 100% and volume fractions such as 0.2 may equate to 20%.

In an embodiment, a 2D filler particle may be a particle that has two dimensions with a magnitude that is significantly greater than a magnitude of a third dimension. A value being significantly greater than another value may refer to a difference by at least one order of magnitude. For example, 10 nm is significantly greater than 1 nm. In some embodiments, the length and width of the filler particle may both be approximately 10 nm or greater, and a thickness of the filler particle may be approximately 1 nm or less.

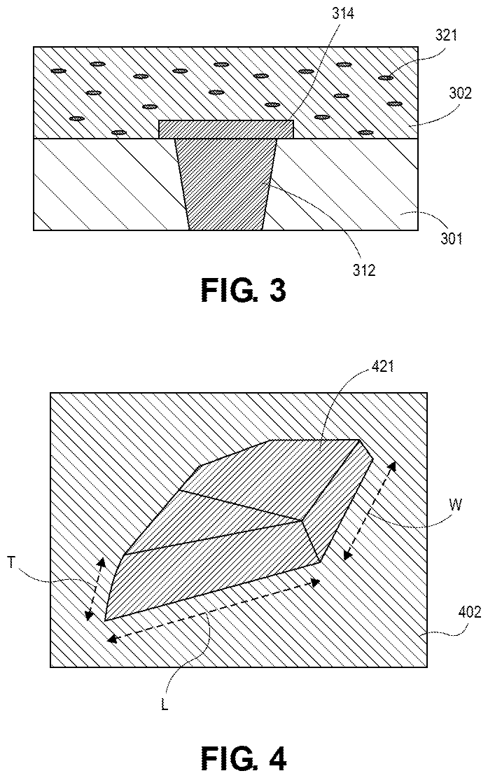

Referring now to FIG. 3, a cross-sectional illustration of a portion of a package substrate is shown, in accordance with an embodiment. The package substrate may comprise a first layer 301. The first layer 301 may be a core (e.g., an organic core, a glass core, or the like). Alternatively, the first layer 301 may be a buildup layer. In some embodiments, the first layer 301 may comprise a PID. Though, other buildup layer materials may also be used in some embodiments.

In an embodiment, a via 312 may be provided through the first layer 301. As shown, the via 312 may include tapered sidewalls. Tapered sidewalls may be indicative of a laser drilling or laser assisted etching process. Though, in other embodiments, the via 312 may have substantially vertical sidewalls. For example, vertical sidewalls may be provided when a lithography process is used to form the opening for the via 312. In an embodiment, a pad 314 may be provided over the via 312. The pad 314 and the via 312 may both comprise copper in some embodiments. Other electrically conductive material (e.g., seed layers, barrier layers, etc.) may also be included as part of the via 312 and/or the pad 314.

In an embodiment, a PID 302 may be provided over the first layer 301. The PID 302 may be applied with any suitable deposition process, such as lamination or the like. In some embodiments, the PID 302 may be a different material than the first layer 301. In other embodiments, the PID 302 and the first layer 301 may comprise substantially the same material. The PID 302 may comprise fillers 321. The fillers 321 may be 2D filler particles. For example, the length and width dimensions of the fillers 321 may be at least a magnitude greater than a thickness of the fillers 321. In an embodiment, the fillers 321 have a volume fraction that minimizes interference with the lithography process. For example, the volume fraction of the fillers 321 may be approximately 0.20 or less, approximately 0.10 or less, or approximately 0.05 or less.

In one embodiment, the fillers 321 may comprise exfoliated 2D clay nanofillers or organo-functionalized 2D clays. In some instances, ligands may be provided on the exfoliated 2D clay nanofillers in order to mitigate agglomeration. 2D clay nanofillers may have any suitable clay composition. For example, the clay composition may include sodium, magnesium, lithium, silicon, oxygen, carbon, nitrogen and/or hydrogen. Other elements may also be included in various clay compositions as well.

In another embodiment, the fillers 321 may comprise 2D covalent organic framework (COF) nanofillers. COF nanofillers are a class of materials that form 2D structures through reactions between organic precursors resulting in strong, covalent bonds to afford porous, stable, and crystalline materials. Selection of COF secondary building units (SBUs), or precursors, can yield a final structure that is predetermined, and modified with exceptional control enabling fine-tuning of material properties. As such, the 2D COF nanofillers can be tuned chemically to maximize dispersion in the PID 302.

In yet another embodiment, carbon nanotubes (CNTs) can be used as the fillers 321. CNTs with low loading enable reductions in CTE. Additionally, CNTs may potentially improve photo patterning capabilities by preventing light bleeding. This can further improve the resolution of the PID 302.

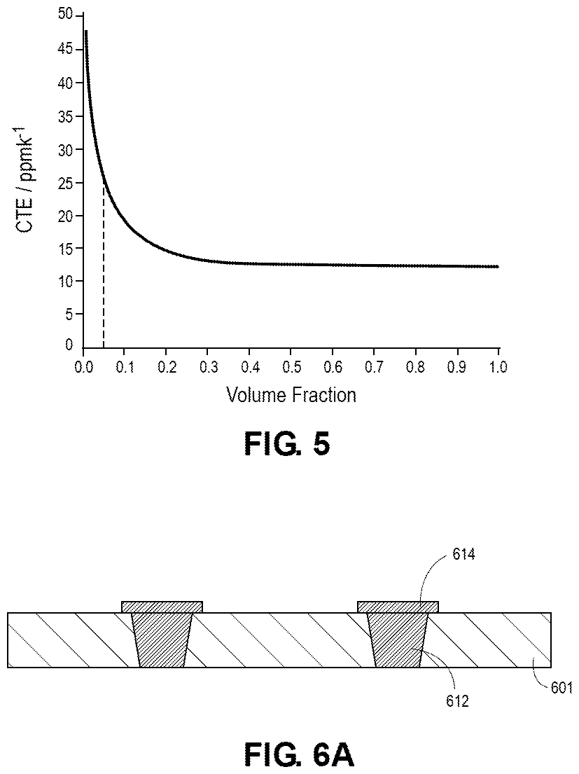

Referring now to FIG. 4, a zoomed in illustration of a filler 421 in a PID 402 matrix is shown, in accordance with an embodiment. The filler 421 may have angular surfaces typical of crystalline materials. Though, in some embodiments, curved edges or surfaces may also be included. The filler 421 may generally be characterized by having a length L, a width W, and a thickness T. In an embodiment, the length L and the width W may be an order of magnitude greater than the thickness T. Such a configuration may be considered a high aspect ratio feature in some instances. Other terms that may be used to describe the filler 421 are a platelet material or a sheet based material.

In an embodiment, the length L and the width W may be approximately 10 nm or greater, and the thickness T may be approximately 1 nm or less. While length L and width W are described as being the larger dimensions, it is to be appreciated that a 2D shape may include any two of the dimensions that are significantly larger than the third dimension. For example, an embodiment may include a length L and a thickness T that are significantly larger than a width W. In an embodiment, the structure of the filler may be visible through the use of microscopy techniques such as a transmission electron microscope (TEM) or a scanning electron microscope (SEM).

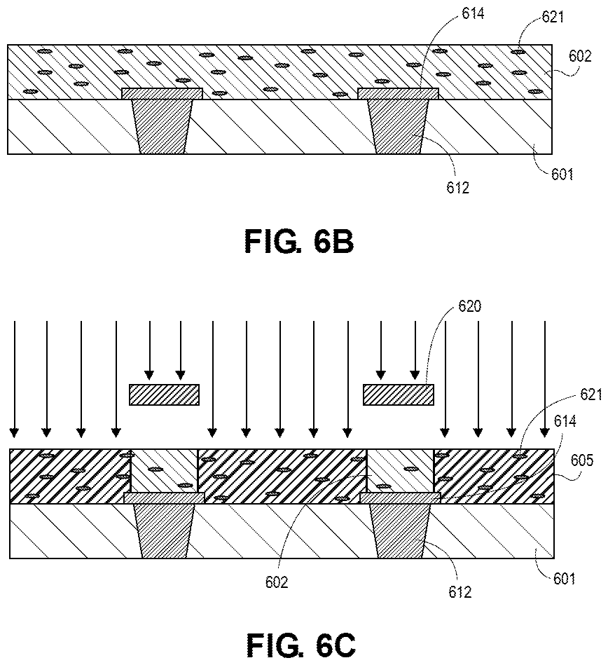

Referring now to FIG. 5, a graph of the CTE of a 2D filler particle with respect to volume fraction is shown for an exemplary 2D material, in accordance with an embodiment. In the particular embodiment shown in FIG. 5, the 2D filler particle is a 2D clay material. Though, other types of 2D filler particles (such as those described in greater detail above) will exhibit similar characteristics.

As shown, at a volume fraction of approximately 0.0 (i.e., no 2D filler particles), the CTE of the material approaches 50 ppm/K. As indicated by the steep slope of the line, small increases in volume fraction provide significant improvements (i.e., reductions) in the CTE. For example, a dashed line highlights the CTE at a volume fraction of approximately 0.05. As shown, at 0.05, the CTE is reduced almost in half to approximately 25 ppm/K. Reductions to the CTE continue until reaching a volume fraction around 0.2. Thereafter, the CTE remains generally flat for higher volume fractions. Accordingly, volume fractions up to approximately 0.2 may be used to reduce CTE. Though, the majority of the improvement comes from the filler loading up to approximately 0.05 volume fraction. At such low loading percentages, the photolithography properties of the PID are not negatively impacted, and overall improved material properties may be obtained.

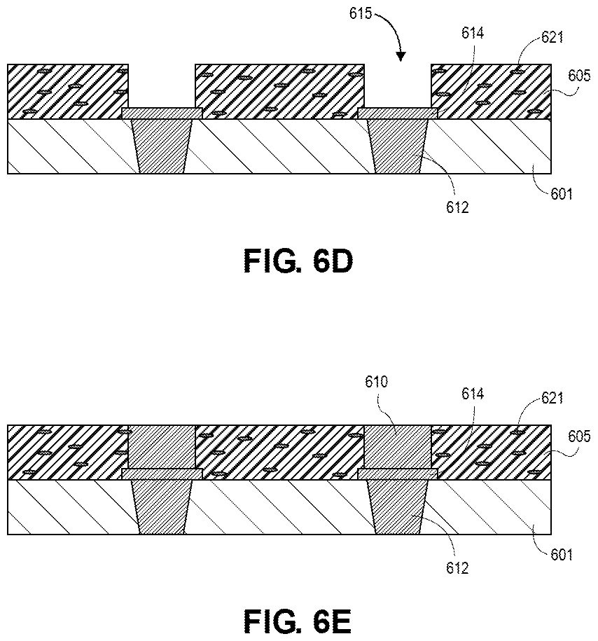

Referring now to FIGS. 6A-6E, a series of cross-sectional illustrations depicting a process for forming a package substrate using a PID with 2D filler particles is shown, in accordance with an embodiment. While shown as being part of a package substrate, it is to be appreciated that 2D filler loaded PID materials may be used for other purposes in semiconductor fabrication manufacturing, such as at wafer level processes.

Referring now to FIG. 6A, a cross-sectional illustration of a first layer 601 in a package substrate is shown, in accordance with an embodiment. The first layer 601 may be a core layer. For example, the first layer 601 may be an organic core, a glass core, or the like. However, it is to be appreciated that the first layer 601 may be any of the layers in a package substrate. In some instances (e.g., when the first layer 601 is a core), the first layer 601 may not be a PID. However, in other instances the first layer 601 may be a PID.

The first layer 601 may include a via 612. The via 612 may have tapered sidewalls in some instances. Tapered sidewalls may be indicative of a laser drilling or a laser assisted etching process. However, in some embodiments, the via 612 may have substantially vertical sidewalls. Such embodiments may be exhibited when a lithography process is used to pattern the opening for the via 612. The via 612 may comprise an electrically conductive material, such as copper.

In an embodiment, a routing layer may be provided over the first layer 601. As shown in FIG. 6A, the routing layer may include pads 614 that are provided over the via 612. The pads 614 may include an electrically conductive material, such as copper. In an embodiment, traces (not shown) may also be provided over the first layer 601. In subsequent processing operations, the pads 614 may be used as a seed layer in order to plate up overlying vias.

Referring now to FIG. 6B, a cross-sectional illustration of the first layer 601 after a PID 602 is provided over a top surface of the first layer 601, in accordance with an embodiment. In an embodiment, the PID 602 may be a dielectric material that includes a solubility switch mechanism. For example, a PAG may be included in the PID 602. Upon exposure to a particular wavelength of electromagnetic radiation, the PAG generates an acid that initiates a cross-linking response in the PID 602. Depending on the tone of the PID 602, the cross-linked regions or the unaltered regions are removed during developing.

In an embodiment, the PID 602 may comprise 2D fillers 621. The 2D fillers 621 may comprise exfoliated 2D clay nanofillers, 2D COF nanofillers, or CNTs. More detailed descriptions of such fillers are provide above. In an embodiment, the 2D fillers 621 may comprise a low volume fraction of the PID 602. For example, the volume fraction of the 2D fillers 621 may be approximately 0.2 or less, approximately 0.1 or less, or approximately 0.05 or less. The resulting CTE of the PID 602 may be approximately 25 ppm/K or less in some embodiments.

In an embodiment, the PID 602 may be provided over the first layer 601 with any suitable deposition process. In one instance, the PID 602 may be laminated over the first layer 601. In some embodiments, the PID 602 may be baked or otherwise treated after deposition. Though, other deposition processes may also be used.

Referring now to FIG. 6C, a cross-sectional illustration of the PID 602 during an exposure process is shown, in accordance with an embodiment. In an embodiment, the exposure process may include a mask 620 or the like. Openings in the mask 620 allow for electromagnetic radiation (indicated by the arrows) to pass through the mask 620 and interact with the underlying PID 602. As shown, the mask 620 may be oriented so that the openings are adjacent to the pads 614 on the first layer 601.

As shown, the PID 602 is converted to include exposed regions 605 in the regions that interact with the electromagnetic radiation. The exposed regions 605 may be regions of higher cross-linking than the remainder of the PID 602. The increased cross-linking percentage may be attributable to the activation of PAGs or the like. In an embodiment, the electromagnetic radiation may be produced by a mercury or a mercury-xenon lamp and include electromagnetic radiation at a wavelength between approximately 360 nm and approximately 420 nm. Further, due to the low volume fraction of the 2D fillers 621, the electromagnetic radiation is not significantly reflected or absorbed by materials other than the PAGs. As such, lithography efficiency and accuracy is improved compared to conventional filler loading processes.

Referring now to FIG. 6D, a cross-sectional illustration of the exposed PID 605 after a developing process is shown, in accordance with an embodiment. In an embodiment, the developing process may include a wet chemistry. The wet chemistry selectively etches the unexposed regions 602 in order to form openings 615 through the exposed PID 605. The openings 615 may be aligned over the pads 614. In some embodiments, a width of the opening 615 is narrower than a width of the pad 614. Further, in some embodiments, the sidewalls of the openings 615 are substantially vertical.

Referring now to FIG. 6E, a cross-sectional illustration of the exposed PID 605 after vias 610 are plated in the openings 615 is shown, in accordance with an embodiment. In an embodiment, the vias 610 may be plated with any suitable plating process. In one embodiment, the plating may be an electroless plating process, an electrolytic plating process, or the like. The pad 614 at the bottom of the opening 615 may function as a seed layer in order to plate up the via 610. In other embodiments, a seed layer (not shown) may be provided over the surfaces of the exposed PID 605 in order to enable plating in the opening 615 and over the top surface of the exposed PID 605.

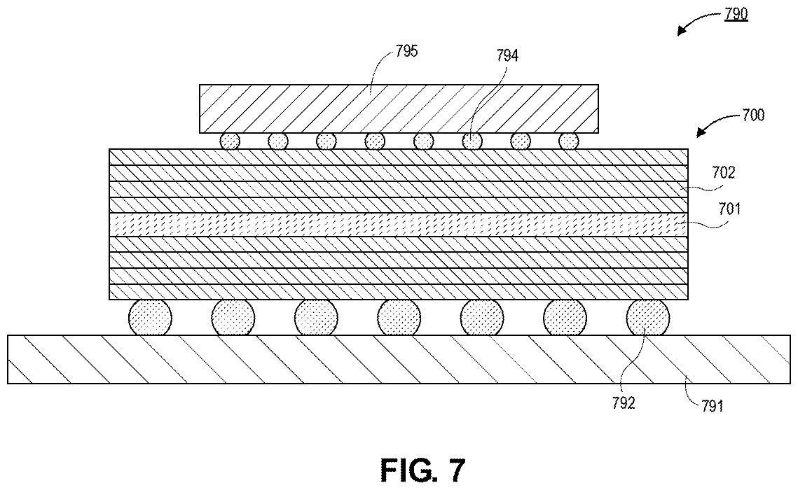

Referring now to FIG. 7, a cross-sectional illustration of a computing system 790 is shown, in accordance with an embodiment. In an embodiment, the computing system 790 comprises a board 791, such as a printed circuit board (PCB). The board 791 may be coupled to a package substrate 700 by interconnects 792. The interconnects 792 may include solder balls, sockets, or any other suitable interconnect architecture.

In an embodiment, the package substrate 700 may comprise a core 701. The core 701 may be an organic core 701 or a glass core 701. Buildup layers 702 may be provided over and under the core 701. More particularly, the buildup layers 702 may comprise PIDs. The layers of PID may comprise 2D filler particles, such as those described in greater detail above. The 2D filler particles may have a volume fraction of approximately 0.2 or less, approximately 0.1 or less, or approximately 0.05 or less. Conductive routing (e.g., pads, traces, vias, etc.) may be provided on and/or in the PIDs of the buildup layers 702.

In an embodiment, one or more dies 795 may be coupled to the package substrate 700 by interconnects 794. The interconnects 794 may be solder balls, copper bumps, or any other first level interconnect (FLI) architecture. The one or more dies 795 may comprise compute dies, such as a central processing unit (CPU), a graphics processing unit (GPU), an XPU, a system on a chip (SoC), a communications die, a memory, or the like.

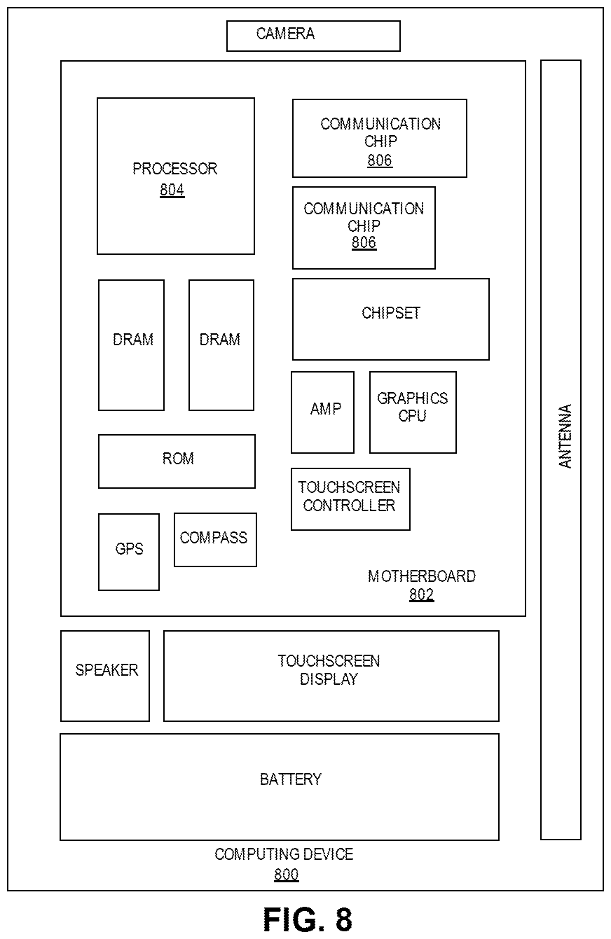

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of an electronic package that comprises a package substrate with PID layers that are filled with 2D nanofiller particles, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be part of an electronic package that comprises a package substrate with PID layers that are filled with 2D nanofiller particles, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a package substrate, comprising: a first layer; a second layer over the first layer, wherein the second layer comprises a dielectric material including sulfur; and fillers within the second layer, wherein the fillers have a volume fraction that is less than approximately 0.2.

Example 2: the package substrate of Example 1, wherein the volume fraction is less than approximately 0.1.

Example 3: the package substrate of Example 2, wherein the volume fraction is less than approximately 0.05.

Example 4: the package substrate of Examples 1-3, wherein the fillers comprise two dimensional (2D) clay nanofillers.

Example 5: the package substrate of Example 4, wherein the 2D clay nanofillers comprise ligands.

Example 6: the package substrate of Examples 1-3, wherein the fillers comprise two dimensional (2D) covalent organic framework (COF) nanofillers.

Example 7: the package substrate of Examples 1-3, wherein the fillers comprise carbon nanotubes (CNTs).

Example 8: the package substrate of Examples 1-7, wherein the dielectric material comprises a photoimageable dielectric (PID) material.

Example 9: the package substrate of Examples 1-8, wherein the fillers have a thickness that is approximately Inm or less, and wherein the fillers have a length that is approximately 10 nm or greater.

Example 10: the package substrate of Examples 1-9, further comprising: a via through the second layer, wherein the via comprises an electrically conductive material.

Example 11: a package substrate, comprising: a core; and buildup layers over and under the core, wherein the buildup layers comprise: a photoimageable dielectric (PID) with two dimensional (2D) filler particles that have a volume fraction that is approximately 0.1 or less.

Example 12: the package substrate of Example 11, wherein the 2D filler particles comprise clay nanofillers.

Example 13: the package substrate of Example 12, wherein the clay nanofillers comprise ligands.

Example 14: the package substrate of Example 11, wherein the 2D filler particles comprise covalent organic framework (COF) nanofillers.

Example 15: the package substrate of Example 11, wherein the 2D filler particles comprise carbon nanotubes (CNTs).

Example 16: the package substrate of Examples 11-15, further comprising electrically conductive routing through the buildup layers.

Example 17: the package substrate of Examples 11-16, wherein a coefficient of thermal expansion (CTE) of the second layer is approximately 25 ppm/K or less.

Example 18: an electronic system, comprising: a board; a package substrate coupled to the board, wherein the package substrate comprises a photoimageable dielectric (PID) that has two dimensional filler particles with a volume fraction of approximately 0.1 or less; and a die coupled to the package substrate.

Example 19: the electronic system of Example 18, wherein the two dimensional filler particles comprise one or more of clay nanofillers, covalent organic framework (COF) nanofillers, and carbon nanotube (CNT) nanofillers.

Example 20: the electronic system of Example 18 or Example 19, wherein the electronic system is part of a personal computer, a server, a mobile device, a tablet, or an automobile.

What is claimed is:

1. A package substrate, comprising:
a first layer;
a second layer over the first layer, wherein the second layer comprises a dielectric material including sulfur; and
fillers within the second layer, wherein the fillers have a volume fraction that is less than approximately 0.2.

2. The package substrate of claim 1, wherein the volume fraction is less than approximately 0.1.

3. The package substrate of claim 2, wherein the volume fraction is less than approximately 0.05.

4. The package substrate of claim 1, wherein the fillers comprise two dimensional (2D) clay nanofillers.

5. The package substrate of claim 4, wherein the 2D clay nanofillers comprise ligands.

6. The package substrate of claim 1, wherein the fillers comprise two dimensional (2D) covalent organic framework (COF) nanofillers.

7. The package substrate of claim 1, wherein the fillers comprise carbon nanotubes (CNTs).

8. The package substrate of claim 1, wherein the dielectric material comprises a photoimageable dielectric (PID) material.

9. The package substrate of claim 1, wherein the fillers have a thickness that is approximately 1 nm or less, and wherein the fillers have a length that is approximately 10 nm or greater.

10. The package substrate of claim 1, further comprising:
a via through the second layer, wherein the via comprises an electrically conductive material.

11. A package substrate, comprising:
a core; and
buildup layers over and under the core, wherein the buildup layers comprise:
a photoimageable dielectric (PID) with two dimensional (2D) filler particles that have a volume fraction that is approximately 0.1 or less.

12. The package substrate of claim 11, wherein the 2D filler particles comprise clay nanofillers.

13. The package substrate of claim 12, wherein the clay nanofillers comprise ligands.

14. The package substrate of claim 11, wherein the 2D filler particles comprise covalent organic framework (COF) nanofillers.

15. The package substrate of claim 11, wherein the 2D filler particles comprise carbon nanotubes (CNTs).

16. The package substrate of claim 11, further comprising electrically conductive routing through the buildup layers.

17. The package substrate of claim 11, wherein a coefficient of thermal expansion (CTE) of the second layer is approximately 25 ppm/K or less.

18. An electronic system, comprising:
a board;
a package substrate coupled to the board, wherein the package substrate comprises a photoimageable dielectric (PID) that has two dimensional filler particles with a volume fraction of approximately 0.1 or less; and
a die coupled to the package substrate.

19. The electronic system of claim 18, wherein the two dimensional filler particles comprise one or more of clay nanofillers, covalent organic framework (COF) nanofillers, and carbon nanotube (CNT) nanofillers.

20. The electronic system of claim 18, wherein the electronic system is part of a personal computer, a server, a mobile device, a tablet, or an automobile.
